(19) United States
(12) Patent Application Publication
(10) Pub. No.: US 2015/0206977 A1
(43) Pub. Date: Jul. 23, 2015

(54) METAL OXIDE TRANSISTOR

(71) Applicant: Sharp Kabushiki Kaisha, Osaka (JP)

(72) Inventors: Sumio Katoh, Osaka (JP); Naoki Ueda, Osaka (JP)

(21) Appl. No.: 14/408,529

(22) PCT Filed: Apr. 8, 2013
(86) PCT No.: PCT/JP2013/060583

§ 371 Date: Dec. 16, 2014

(30) Foreign Application Priority Data
Jun. 19, 2012 (JP) 2012-137868

(51) Int. Cl. H01L 29/786; H01L 29/417; H03K 17/687; H01L 29/24

(52) U.S. Cl. CPC H01L 29/7869; H01L 29/24; H01L 29/41733; H01L 29/78648; H03K 17/687

(57) ABSTRACT

Provided is a transistor element in which the state thereof is changed into that of a resistor with a small power consumption without migration and melting of the resistor due to a large current, and physical changes, such as breakdown of an insulating film due to high electric field application, and the state change can be used as a memory element. This metal oxide transistor is provided with: a semiconductor thin film formed of a metal oxide semiconductor; a source electrode and a drain electrode, which are in contact with the semiconductor thin film; and a gate electrode, which faces the semiconductor thin film with a gate insulating film therebetween. In the initial state, the metal oxide transistor exhibits first characteristics in which the metal oxide transistor operates as a transistor element having a drain current changed depending on the gate voltage and the drain voltage, and when a drain current at or above a prescribed current density is made to flow for a prescribed time, the characteristics transition to second characteristics in which the drain current depends less on the gate voltage compared with the first characteristics, the drain current depends mainly on the drain voltage, and ohmic resistive characteristics are exhibited irrespective of the gate voltage.

### TECHNICAL FIELD

The present invention is related to a metal oxide transistor having a channel region formed of a metal oxide semiconductor, and in particular, is related to a metal oxide transistor that can be used as a non-volatile storage element.

### BACKGROUND ART

Currently, eFUSE type elements shown in Patent Document 1 and insulation breakdown type elements shown in Patent Document 2 are known as storage elements that can be used as ROM (read only memory).

The memory element described in Patent Document 1 has a layered structure that is the same as the wiring structure used in a typical logic LSI process including a polysilicon layer, a silicide layer, and a silicon nitride film layer. In addition, the memory element is formed as a resistor having two terminals: a cathode and an anode. This resistor is heated by applying a large electric current thereto, causing the atoms in the metal wiring material to migrate in the direction of the current flow or melting the resistor so as to cause a disconnection therein, thereby changing the resistance between the two terminals. Other examples include those in which the resistance is changed by disconnecting the wiring line by radiating laser or the like onto the resistor instead of applying a large current.

The memory element (antifuse) described in Patent document 2 includes a MOS transistor and writing is performed thereon by applying a strong electric field to the gate insulating film to cause a breakdown in the insulator.

As another example, Patent Document 3 discloses an element that is a transistor element having a drain electrode and a source electrode that are disposed on an insulating film with a gap therebetween, a physical property transformation layer formed on an insulating film in an area between the drain electrode and the source electrode, a high dielectric film that is stacked on the physical property transformation layer, and a gate electrode formed on the high dielectric film. If the voltage applied to the gate electrode is 0V and the voltage between the drain electrode and the source electrode exceeds the first threshold voltage, then the resistance of the physical property transformation layer is decreased and the physical property transformation layer becomes conductive. On the other hand, if a voltage that is greater than 0V is applied to the gate electrode, because a channel is formed in the lower layer of the physical property transformation layer, if the voltage between the drain electrode and the source electrode is greater than a second threshold voltage that is smaller than the first threshold voltage, the physical property transformation layer becomes conductive. Therefore, by setting the voltage between the drain electrode and the source electrode to be between the first threshold voltage and the second threshold voltage, the transistor element can be used as a switching element that switches between conductive and non-conductive states through the application of gate voltage.

Additionally, Patent Document 4 discloses a variable resistor that is a three terminal type variable resistor having first and second electrodes, a variable resistor that is electrically connected to both the first and second electrodes, and a control electrode facing the variable resistor through a dielectric layer (equivalent to a gate insulating film). If a read voltage is applied between the first and second electrodes while a voltage is applied to the control electrode, then the resistance between the first and second electrodes is temporarily lowered, and therefore, a large read current can be obtained with a small read voltage, thereby allowing the readout margin to be increased.

### RELATED ART DOCUMENTS

### Patent Documents

Patent Document 1: US Patent No. 7960809 Specification

Patent Document 2: US Patent No. 6775171 Specification

Patent Document 3: Japanese Patent Application Laid-Open Publication No. 2006-245589

Patent Document 4: Japanese Patent Application Laid-Open Publication No. 2010-153591

### SUMMARY OF THE INVENTION

### Problems to be Solved by the Invention

The eFUSE type memory element described in Patent Document 1 is configured to be disconnected by melting by applying a large current thereto, and thus, the resistance of the element disconnected by writing varies greatly. Furthermore, because the fuse material is melted and disconnected by heating to high temperatures, there is a risk that the melted material scatters to surrounding areas, and a risk that characteristics of adjacent materials change due to heating of the element. As a result, a high density circuit cannot be disposed in the vicinity of the memory element, and thus, high integration is inhibited in a case in which a semiconductor integrated circuit is configured using the memory element and , thereby causing an increase in chip size.

The memory element described in Patent Document 2 performs writing by breaking down the insulating film, and therefore needs a high voltage to be applied to the gate electrode. Due to this, the peripheral circuit for writing needs to be large in order to have a high withstand voltage, and if the memory element is used to form the semiconductor integrated circuit, high integration of a configuration is inhibited, thereby causing an increase in the chip size.

In the transistor element disclosed in Patent document 3, the current/voltage characteristics between the drain electrode and the source electrode change depending on the applied gate voltage, and therefore, in order to use the transistor element as a switching element that switches between conductive and non-conductive states between the drain electrode and the source electrode through the application of the gate voltage, it is necessary for the voltage between the drain electrode and source electrode be maintained between the first threshold voltage and the second threshold voltage regardless of the transistor element being conductive or non-conductive. Furthermore, the transistor element can be used as a switching element, but is not suitable for a non-volatile memory element.

The variable resistor described in Patent Document 4 is essentially a resistor that switches between a low resistance state and a high resistance state. Thus, the variable resistor does not function as a transistor element and cannot be used as a switching element.

The present invention was made in view of the above-mentioned problems, and an object thereof is to provide a transistor element that can change states to be a resistor, the state change occurring with a small power consumption, without physical changes such as migration and melting of the resistor due to a large current, and breakdown of an insulating film due to the application of a high electric field, and the state change can be used as a memory element.

### Means for Solving the Problems

In order to achieve the above-mentioned aim, the present invention provides a metal oxide transistor including: a semiconductor thin film formed of a metal oxide semiconductor; a source electrode in contact with a portion of the semiconductor thin film; a drain electrode in contact with another portion of the semiconductor thin film; and a gate electrode facing the semiconductor thin film through a gate insulating film, wherein the metal oxide transistor has, as an initial state, first characteristics, which are transistor element, in which a drain current flowing from the drain electrode to the source electrode changes depending on a gate voltage applied between the gate electrode and the source electrode and a drain voltage applied between the drain electrode and the source electrode, wherein when the drain current having a prescribed current density or greater that induces a change from the first characteristics is caused to flow through the semiconductor thin film for a prescribed period of time, the dependence of the drain current on the gate voltage is smaller in the second characteristics than in the first characteristics, whereby changes in the drain current primarily depends on the drain voltage and not on the gate voltage, exhibiting ohmic resistive characteristics, wherein, in the first characteristics, there exists a specific voltage range of the gate voltage at which enters a minute current state, the minute current state being such that an absolute value of a unit drain current that is the drain current for each unit channel width is confined to be less than or equal to 1×10⁻¹⁴ A/μm at least when an absolute value of the drain voltage is in a range of 0.1V to 10V, and wherein, in the second characteristics, the absolute value of the unit drain current is greater than or equal to 1×10⁻¹¹ A/μm regardless of the gate voltage, when the drain voltage is at least within a range of 0.1V to 10V, even if the gate voltage is within the specific voltage range.

The ohmic resistive characteristics in the second characteristics refer to when the differential resistance for the unit channel width that is the differential change of the drain voltage is divided by the unit drain current has a prescribed value that is not 0. In other words, the current voltage characteristics line between the drain voltage and the unit drain current passes through the starting point (drain voltage=0V, unit drain current=0A/μm).

In addition, it is preferable that the metal oxide transistor be a thin film transistor in which the semiconductor thin film, the source electrode, the drain electrode, the gate electrode, and the gate insulating film are formed on an insulating substrate.

In addition, it is preferable that the metal oxide semiconductor include In, Ga, or Zn, and in particular, include InGaZnOx.

In addition, it is preferable that the metal oxide semiconductor have the current density of the drain current be greater in a portion of the semiconductor thin film than in another portion.

In addition, it is preferable that an area sandwiched by the drain electrode and the source electrode have a U shape.

In addition, it is preferable that the gate insulating film have a multilayer structure having at least a first insulating film and a second insulating film having higher permittivity than the first insulating film, wherein the first insulating film has a lower hydrogen concentration therein than the second insulating film after being formed, and wherein the first insulating film is formed between the semiconductor thin film and the second insulating film.

In addition, it is preferable that the metal oxide transistor have a second gate electrode facing the semiconductor thin film through an insulating film other than the gate insulating film, the second gate electrode being provided across from the gate electrode with the semiconductor thin film therebetween.

The metal oxide transistor having the above-mentioned characteristic, wherein the change from the first characteristics to the second characteristics occurs due to a change in composition ratio of elements forming the metal oxide semiconductor of the semiconductor thin film through joule heat generated by the drain current.

The present invention provides a semiconductor device including the metal oxide transistor.

In addition, the present invention provides a method of driving the metal oxide transistor, the method including: causing the drain current having the prescribed current density or greater to flow between the drain electrode and the source electrode for the prescribed period of time when the metal oxide transistor is exhibiting the first characteristics, so as to cause the metal oxide transistor to make the transition from the first characteristics to the second characteristics.

### EFFECTS OF THE INVENTION

The metal oxide transistor with the above-mentioned characteristics, in the initial state under the first characteristics, can be used as a transistor element in which the drain current changes depending on the gate voltage and drain voltage. Furthermore, a specific voltage range exists in which the absolute value of the unit drain current, which is the drain current for each unit channel width, is in a minute current state or a virtually non-conductive state less than or equal to 1×10⁻¹⁴ A/μm at least when the absolute value of the drain voltage is 0.1V to 10V. Therefore, the metal oxide transistor can be used as a switching element that switches between conductive and non-conductive states between the drain electrode and the source electrode by shifting the gate voltage between the specific voltage range and another voltage range.

Furthermore, the metal oxide transistor with the above-mentioned characteristics can be used as a resistor. This is because when a drain current at or above a prescribed current density is made to flow in the semiconductor thin film for a prescribed time, the characteristics shift to the second characteristics in which the drain current exhibits ohmic resistive characteristics regardless of the gate voltage. As a result, the function of the metal oxide transistor as a transistor element or a switching element is lost and the metal oxide transistor acts as a resistor and therefore can be used as a resistor. If the gate voltage is set within the specific voltage range, under the first characteristics, the metal oxide transistor is in a non-conductive state, and under the second characteristics, the metal oxide transistor acts as a resistor. Therefore, the metal oxide transistor can be determined to be at the first characteristics or the second characteristics according to the conductive state between the drain electrode and the source electrode, and thus, the metal oxide transistor can be used as a memory element.

Furthermore, by forming a plurality of metal oxide transistors with the above-mentioned characteristics, some of the metal oxide transistors can be used only as transistor elements or switching elements, and have other metal oxide transistors be programmed to have either the first characteristics or the second characteristics. As a result, the metal oxide transistors can be used as memory elements that store information in a non-volatile manner. In other words, using the metal oxide transistors having the same characteristics, the memory element and the peripheral circuit thereof can be formed.

Furthermore, by including the memory element of other metal oxide transistors into the logic circuit, a programmable logic device can be configured. Also, other metal oxide transistors can be used not as memory elements but simply as resistors. Furthermore, a composite device having various functions can be configured by combining a transistor element, a switching element, a memory element, and a resistor.

If the metal oxide transistor with the above-mentioned characteristics is a thin-film transistor, the thin-film transistor can be formed on the insulating substrate where a liquid crystal display device or the like is formed on the periphery of this display device and be used as a component of the periphery circuit of the display device. Also, on the integrated circuit formed of bulk-type transistors, an integrated circuit of high density and high functionality can be formed and be provided by stacking circuits formed of metal oxide transistors that are thin film transistors.

### BRIEF DESCRIPTION OF THE DRAWINGS

FIG. 1 schematically shows a plan view and a cross-sectional view of one example of an element structure of a metal oxide transistor of Embodiment 1 of the present invention.

FIG. 2 schematically shows cross-sections of an element during a manufacturing process of the metal oxide transistor of Embodiment 1 of the present invention.

FIG. 3 is a drawing for describing a channel length and a channel width of the metal oxide transistor of the present invention.

FIG. 4 shows a plan view and a cross-sectional view schematically showing another example of an element structure of the metal oxide transistor of Embodiment 1 of the present invention.

FIG. 5 shows the Ids−Vgs characteristics and the Ids−Vds characteristics in an initial state of the metal oxide transistor of the present invention.

FIG. 6 shows the Ids−Vgs characteristics and the Ids−Vds characteristics after writing is performed on the metal oxide transistor of the present invention.

FIG. 7 shows together the Ids−Vds characteristics of FIGS. 5 and 6 near the starting point.

FIG. 8 shows together the Ids−Vgs characteristics of FIGS. 5 and 6.

FIG. 9 shows the relationship between the respective differential resistances (dVds/dIds) of the first and second characteristics and the drain voltage Vds.

FIG. 10 shows an example of the relationship between the writing time during writing in the metal oxide transistor of the present invention and the unit drain current.

FIG. 11 shows an example of the relationship between the writing time, and the gate voltage Vgs and drain voltage Vds for two types of element structures including a structure in which the gap between the drain electrode and the source electrode is in a rectangular shape and a structure in which the gap is in a U shape.

FIG. 12 shows a plan view and a cross-sectional view of a metal oxide transistor of Embodiment 1 of the present invention schematically showing an example of an element.

FIG. 13 is a block diagram showing a schematic configuration of a case in which the metal oxide transistor of the present invention is used in a display device.

FIG. 14 shows a plan view and a cross-sectional view of a metal oxide transistor of Embodiment 2 of the present invention schematically showing an example of an element structure of the metal oxide transistor.

FIG. 15 schematically shows cross-sections of elements at respective steps of a manufacturing process of the metal oxide transistor of Embodiment 2 of the present invention.

FIG. 16 shows a plan view and a cross-sectional view of a metal oxide transistor of Embodiment 3 of the present invention schematically showing an example of an element structure of the metal oxide transistor.

FIG. 17 schematically shows cross-sections of elements at respective steps of a manufacturing process of the metal oxide transistor of Embodiment 3 of the present invention.

FIG. 18 shows a plan view and a cross-sectional view of a metal oxide transistor of another embodiment of the present invention schematically showing an example of an element structure.

### DETAILED DESCRIPTION OF EMBODIMENTS

Below, embodiments of the metal oxide transistor (hereinafter, also referred to as a “present transistor”) are described with reference to drawings.

### Embodiment 1

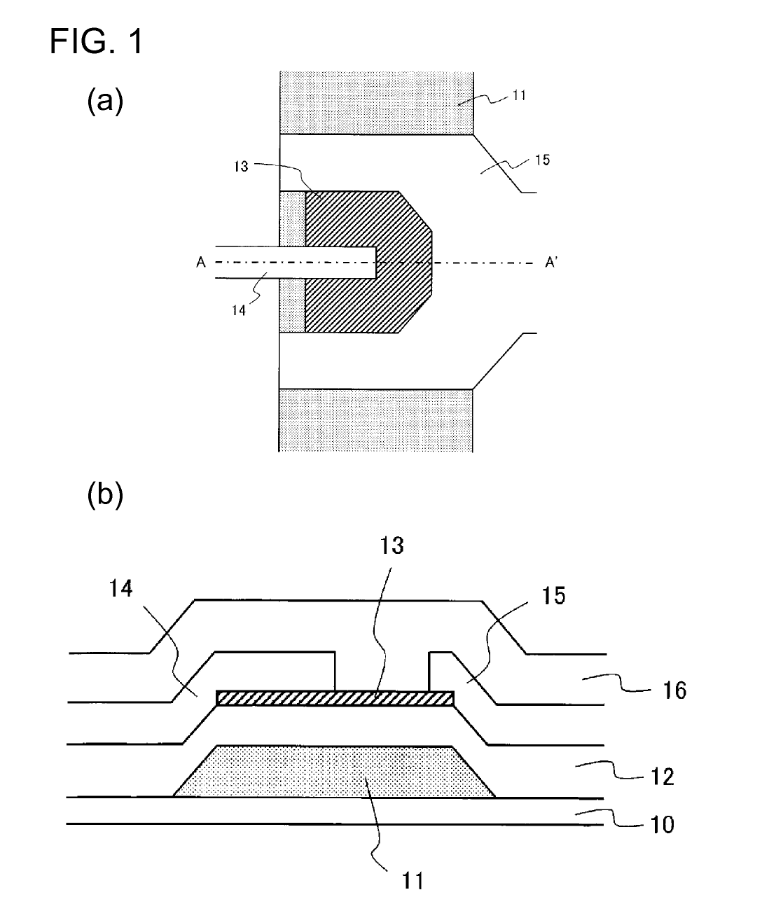

FIG. 1 shows an example of an element structure of a present transistor 1 of Embodiment 1. FIG. 1(a) schematically shows a plan view structure of the transistor 1 and FIG. 1(b) schematically shows a cross-sectional structure of the transistor 1. In the respective figures, main components of the transistor 1 are emphasized, and therefore, the dimensions of the respective components are not always the same as the dimensions of the actual device. FIG. 1(b) is a cross-sectional view of FIG. 1(a) along the line A-A′.

On an insulating substrate 10 such as a glass substrate, the transistor 1 has a gate electrode 11, a first insulating film (gate insulating film) 12 that covers the gate electrode 11, a semiconductor thin film 13 formed of a metal oxide semiconductor, a source electrode 14, a drain electrode 15, and a second insulating film 16 on top of these. The transistor 1 has a similar structure to a thin film transistor (TFT) having a bottom gate structure and being formed on the insulating substrate.

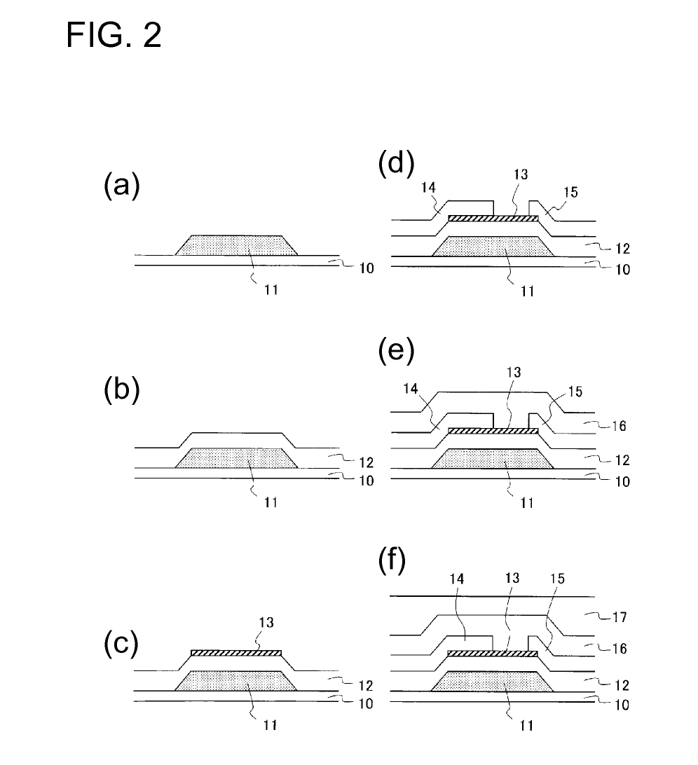

Next, the manufacturing method of the transistor 1 and details of the respective constituting elements are described with reference to the cross-sectional views of FIG. 2. The cross-sections of respective steps shown in FIG. 2 are cross-sections of FIG. 1(a) along the line A-A′.

As shown in FIG. 2(a), the first conductive film is formed on the entire surface of the insulating substrate 10 through sputtering or the like, and the gate electrode 11 is formed by patterning the first conductive film using a known dry etching method. The first conductive film is formed of a single layer film or a multi-layer film having two or more layers, and is made of a conductor formed of an element selected from among aluminum (Al), chromium (Cr), copper (Cu), tantalum (Ta), titanium (Ti), molybdenum (Mo), and tungsten (W), or an alloy or the like having two or more of these elements. A three layer film of Ti/Al/Ti, a three layer film of Mo/Al/Mo, or the like can be used, for example. In the present embodiment, as an example, a three layer film with a Ti layer that is 10 nm to 100 nm in thickness, an Al layer that is 50 nm to 500 nm in thickness, and a Ti layer that is 50 nm to 300 nm in thickness stacked in that order from the bottom is used.

As shown in FIG. 2(b), the gate insulating film 12 is formed by plasma CVD or sputtering on the exposed insulating substrate 10 and the entire surface of the gate electrode 11, for example. The gate insulating film 12 is formed of a multilayer film having a single layer film or a multilayer film of two or more layers selected from among a silicon oxide film (SiO₂), a silicon nitride film (SiN), a silicon nitride oxide film (SiNO), a silicon oxide nitride film (SiON), an aluminum oxide (Al₂O₃), and a tantalum oxide (Ta₂O₅). In the present embodiment, a two layer film having an SiN layer that is 10 nm to 500 nm in thickness and an SiO₂ layer that is 20 nm to 100 nm in thickness, layered in that order from the bottom, is used as an example.

Next, as shown in FIG. 2(c), a metal oxide semiconductor layer having a thickness of 20 nm to 200 nm is formed on the entire surface of the gate insulating film 12, and the semiconductor thin film 13 is formed by a known wet etching method. The semiconductor thin film 13 is formed over a portion of the gate electrode 11 across the gate insulating film 12. In the present embodiment, as a metal oxide semiconductor used for the semiconductor thin film 13, an oxide semiconductor including In, Ga, or Zn, and more preferably, IGZO (InGaZnOx), which is a type of an amorphous oxide semiconductor, is used. IGZO is an n-type metal oxide semiconductor having indium (In), gallium (Ga), zinc (Zn), and oxygen (O) as main components and can be formed in low temperatures. IGZO is also referred to as IZGO or GIZO. The composition ratio of the respective metal elements of IGZO used in the semiconductor thin film 13 is approximately In:Ga:Zn=1:1:1, but even if the composition ratio is adjusted therefrom, the effects of the present invention mentioned later can be attained. The metal oxide semiconductor used in the semiconductor thin film 13 can be formed of an oxide semiconductor other than IGZO such as NiO, SnO₂, TiO₂, VO₂, In₂O₃, or SrTiO₃, or such an oxide semiconductor having various impurities added thereto as long as the characteristics change from the first characteristics to the second characteristics.

Next, as shown in FIG. 2(d), the second conductive film is formed by sputtering on the entirety of the exposed gate insulating film 12 and the semiconductor thin film 13, and the source electrode 14 and the drain electrode 15 are respectively formed by patterning the second conductive film by a known dry etching method. The source electrode 14 and the drain electrode 15 are separated from each other and are respectively in contact with portions of the semiconductor thin film 13. In the present embodiment, as shown in FIG. 1(a), the area between the source electrode 14 and the drain electrode 15 has a U shape in a plan view, as one example. The second conductive film is formed of a single layer film or a multi-layer film, and is made of a conductor formed of an element selected from among aluminum (Al), chromium (Cr), copper (Cu), tantalum (Ta), titanium (Ti), molybdenum (Mo), and tungsten (W), or an alloy or the like having two or more of these elements. A three layer film of Ti/Al/Ti, a three layer film of Mo/Al/Mo, or the like can be used, for example. In the present embodiment, as an example, a three layer film with a Ti layer that is 10 nm to 100 nm in thickness, an Al layer that is 50 nm to 400 nm in thickness, and a Ti layer that is 50 nm to 300 nm in thickness stacked in that order from the bottom is used.

Next, as shown in FIG. 2(e), the second insulating film 16 is formed by plasma CVD or sputtering to cover the entirety of the exposed gate insulating film 12, the semiconductor thin film 13, the source electrode 14, and the drain electrode 15, for example. Next, annealing is performed for 30 minutes to 4 hours at a temperature of 200° C. to 400° C. in air. The second insulating film 16 is formed of a single layer film or a multilayer film of two or more layers selected from among a silicon oxide film (SiO₂), a silicon nitride film (SiN), a silicon nitride oxide film (SiNO), a silicon oxide nitride (SiON) film, aluminum oxide (Al₂O₃), and tantalum oxide (Ta₂O₅). In the present embodiment, a single layer film of SiO₂ having a film thickness of 50 nm to 500 nm is used as an example.

The transistor 1 is manufactured through the respective steps mentioned above. As shown in FIG. 2(f), a third insulating film 17 formed of a photosensitive resin or the like is formed as a planarizing film that planarizes the surface of the second insulating film 16, and then this photosensitive resin film is exposed, developed, and baked. Additionally, etching is performed on the third insulating film 17 and the second insulating film 16 to form contact holes (not shown) therein so as to connect the gate electrode 11, the source electrode 14, the drain electrode 15, and the like to a metal wiring line layer (ITO or the like, for example) formed on the third insulating film. The third insulating film 17 may be formed without forming the second insulating film 16.

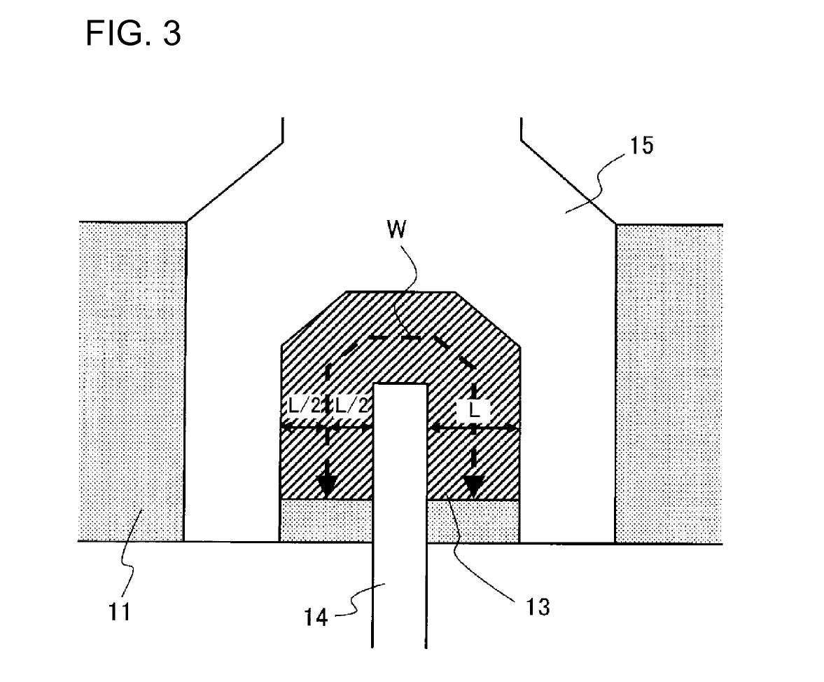

In the present embodiment, the channel length L and the channel width W of the transistor 1 are defined by the length and width of the gap over the semiconductor thin film 13 between the source electrode 14 and the drain electrode 15, and the channel length L corresponds to the distance between the source electrode 14 and the drain electrode 15 over the semiconductor thin film 13. The channel width W is the length of the line through the mid-points on the semiconductor thin film 13 between the source electrode 14 and the drain electrode 15. In the example shown in FIG. 1, the gap between the source electrode 14 and the drain electrode 15 on the semiconductor thin film 13 of the transistor 1 has a U shape in a plan view. Thus, the channel width W of the transistor, as shown in FIG. 3, is the length along a U shaped line (shown as a dotted line) that connects the mid-points between the source electrode 14 and the drain electrode 15, the mid-points all being located at the same distance from the source electrode 14 and the drain electrode 15.

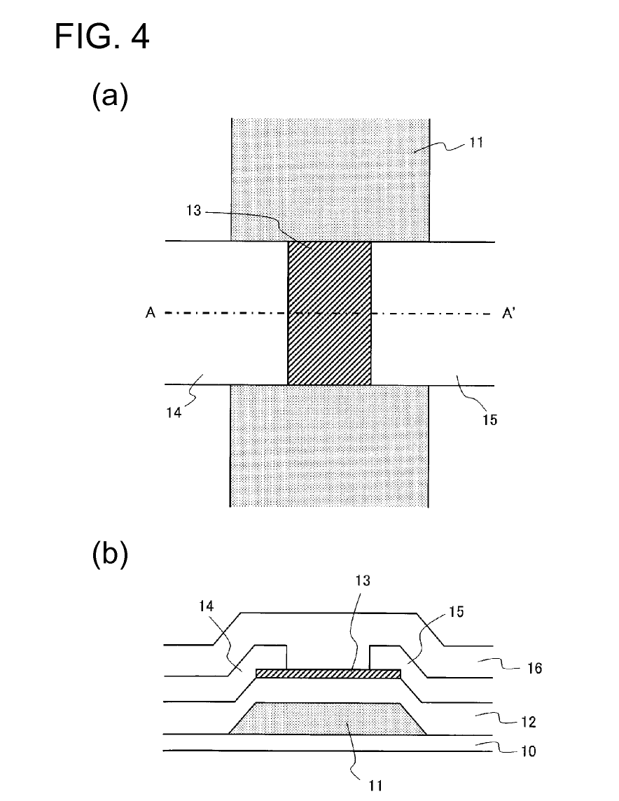

In the example shown in FIG. 1, the gap between the source electrode 14 and the drain electrode 15 on the semiconductor thin film 13 does not need to be in a U shape in a plan view in the transistor 1, and the transistor 1 may be in a rectangular shape as shown in FIG. 4.

Next, the electrical characteristics of the transistor 1 are described. If the above-mentioned IGZO is used as a metal oxide film semiconductor of the semiconductor thin film 13, then the transistor 1 becomes an n-channel transistor. In the initial state right after manufacturing, like a typical thin film transistor, the drain current Ids (current flowing from the drain electrode based on the source electrode) changes depending on the gate voltage Vgs (voltage applied to the gate electrode with reference to the source electrode) and the drain voltage Vds (voltage applied to the drain electrode with reference to the source electrode).

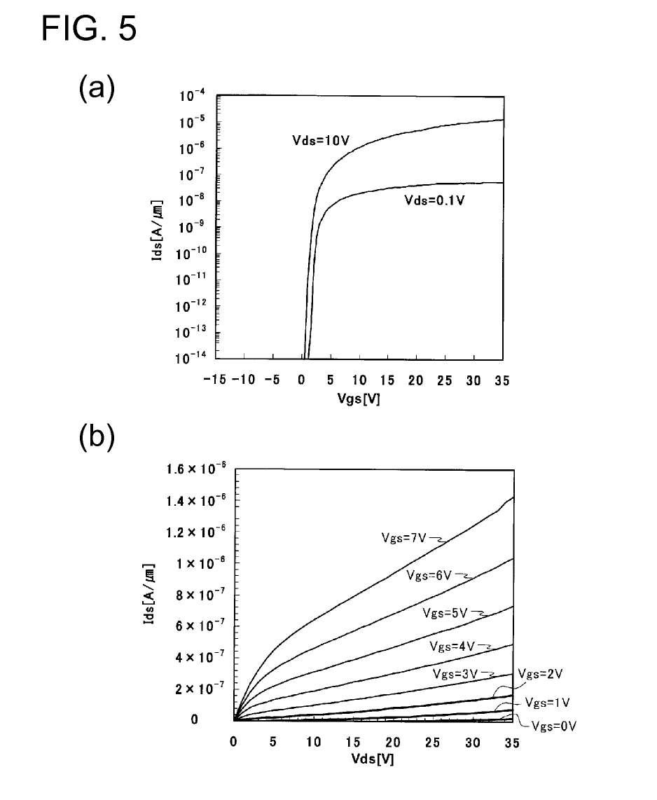

FIG. 5(a) shows the Ids−Vgs characteristics of cases in which Vds=0.1V and Vds=10V during the initial state. FIG. 5(b) shows the Ids−Vds characteristics of cases in which Vgs=0V to 7V (1V step) during the initial state. In the transistor 1 used to measure the characteristics shown in FIG. 5, the gate length L is 4 μm and the gate width W is 20 μm. The shape of the gap mentioned above is rectangular or U shaped. The drain currents Ids of the respective characteristics indicate the value of the unit drain current of the unit gate width (1 μm).

It is clear from FIGS. 5(a) and 5(b) that the transistor 1 in the initial state has characteristics similar to a normal thin film transistor (corresponding to the first characteristics), and if the gate voltage Vgs is within the voltage range of approximately 0.5V or less (corresponding to the specific voltage range), and if the absolute value of the drain voltage is 0.1V to 10V, then the unit drain current is in a minute current state of 1×10⁻¹⁴ A/μm or less and is effectively in an OFF state. In a voltage state in which the gate voltage Vgs exceeds the specific voltage range, the drain current Ids increases together with the gate voltage Vgs and the drain voltage Vds.

By applying to the transistor 1, in the initial state showing the transistor characteristics (first characteristics), a voltage greater than the specific voltage range for circuit operation of a normal transistor element so as to cause a large drain current to flow therethrough, the electrical characteristics of the transistor 1 are changed from the transistor characteristics of the initial state to ohmic resistive characteristics (corresponding to the second characteristics) to locally generate joule heat in the semiconductor thin film 13. In the description below, the operation of changing the electric characteristics of the transistor 1 from the transistor characteristics to the ohmic resistive characteristics is referred to as a writing operation for convenience.

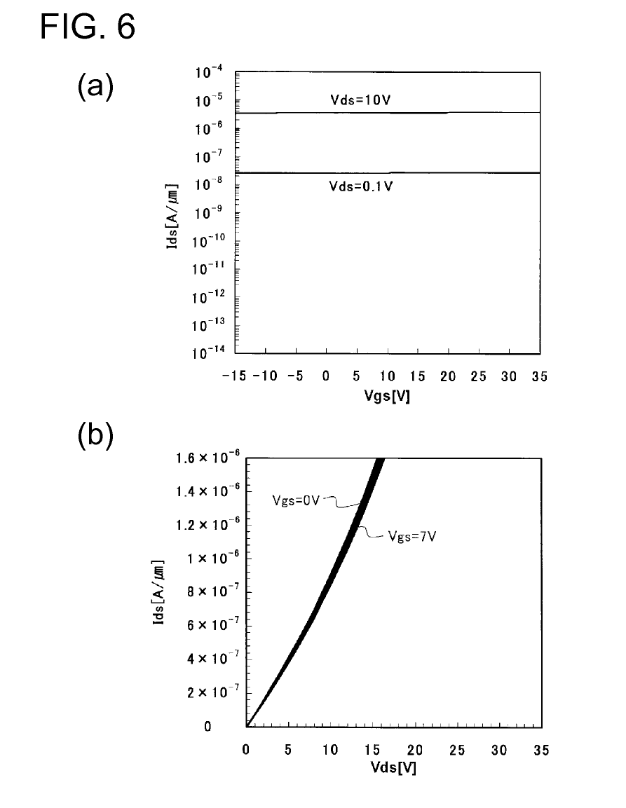

FIG. 6(a) shows the Ids−Vgs characteristics for when Vds=0.1V and Vds=10V after the writing operation. FIG. 6(b) shows the Ids−Vds characteristics for when Vgs=0V to 7V (1V step) after the writing operation. The transistor 1 used to measure the characteristics shown in FIG. 6 is the same transistor 1 used to measure the characteristics in FIG. 5. In the writing operation, Vds=24V and Vgs=30V, and the writing time (weld time of the drain current Ids) is 100 milliseconds. The drain current Ids of the respective characteristics shows the value of the unit drain current of the unit gate width (1 μm).

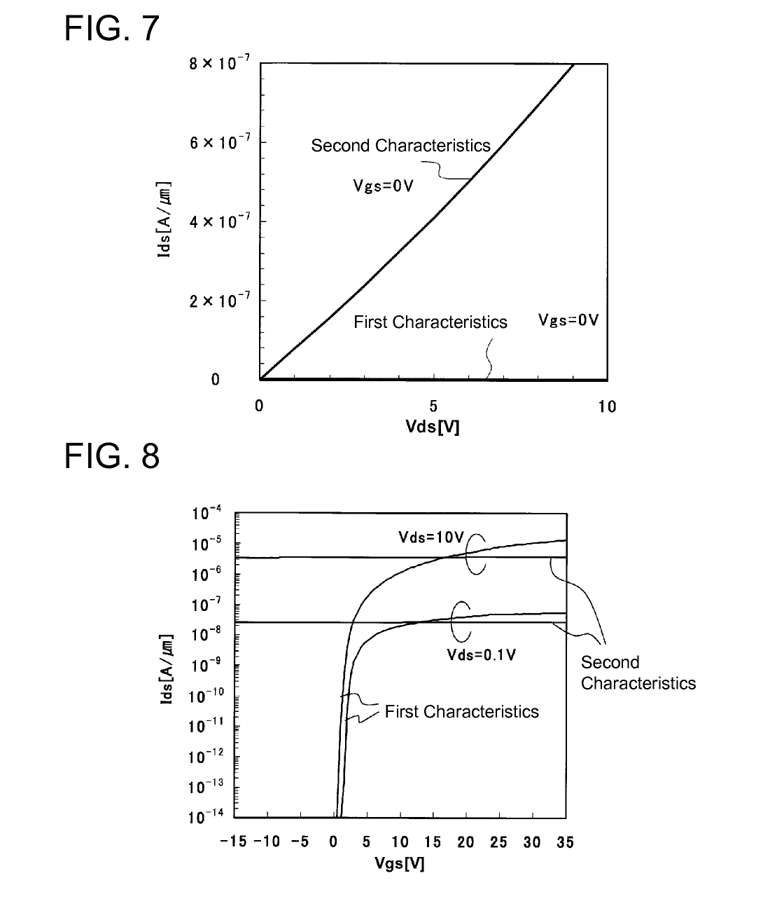

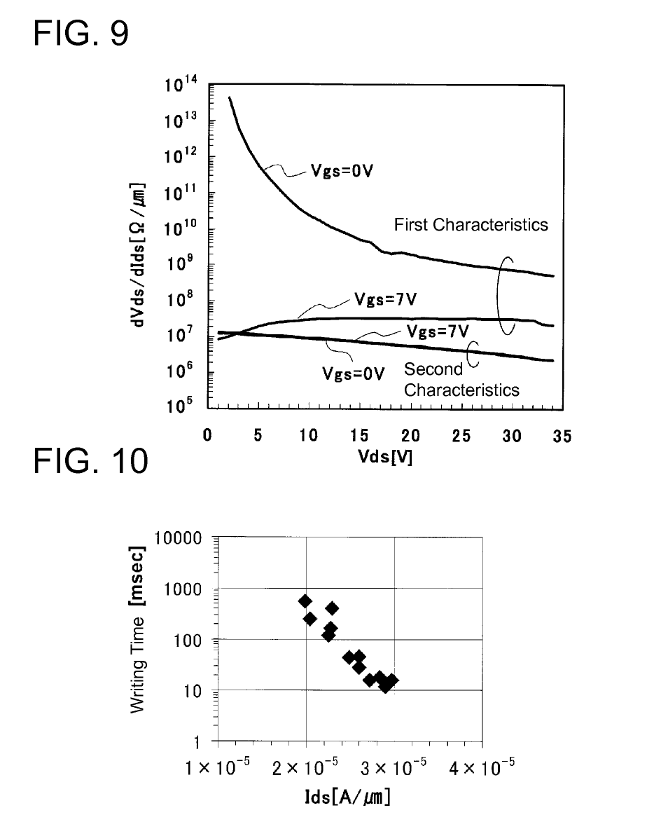

Furthermore, in order to compare the first characteristics to the second characteristics, the Ids−Vds characteristics near the starting point in FIGS. 5(b) and 6(b) are magnified in FIG. 7. In FIG. 8, the Ids−Vgs characteristics under the first characteristics in FIG. 5(a) and the Ids−Vgs characteristics under the second characteristics in FIG. 6(a) are shown together. FIG. 9 shows the relationship between the drain voltage Vds and the differential resistance (dVds/dIds, the unit being Ωμm) that is obtained from the Ids−Vds characteristics under the first characteristics of FIG. 5(b) and the differential resistance obtained from the Ids−Vds characteristics under the second characteristics of FIG. 6(b), when the gate voltages Vgs are 0V and 7V.

It is clear from FIGS. 6(a) and 6(b) that after writing, in the transistor 1, the drain current Ids mostly does not depend on the gate voltage Vgs and mainly changes in response to the drain voltage Vds, and if the drain voltage Vds is constant, the value of the drain current Ids is substantially constant. It is clear from FIGS. 6(b) and 7 that the IV curves of the Ids−Vds characteristics for the respective gate voltages Vgs are in a substantially straight line regardless of the gate voltage Vgs, and has ohmic resistive characteristics that pass through the starting point (Ids=0A/μm, Vds—0V). In other words, the differential resistance (dVds/dlds) has a finite value that is neither infinite nor 0.

It is clear from FIGS. 7 and 8 that in the transistor 1 under the first characteristics of the initial state, the drain current Ids changes primarily based on the gate voltage Vgs, and if the gate voltage Vgs is within the specific voltage range (approximately 0.5V or less) almost no drain current Ids flows, which effectively puts the transistor 1 in the OFF state, but when the transistor 1 shifts to the second characteristics, then a constant current flows therein even within the specific voltage range regardless of the gate voltage Vgs, and when the drain voltage is at least in the range of 0.1V to 10V, the unit drain current becomes 1×10⁻¹¹ A/μm or greater.

It is clear from FIG. 9 that the differential resistance under the first characteristics changes due to the gate voltage Vgs regardless of the drain voltage Vds, but under the second characteristics, the differential resistance does not change in response to the gate voltage Vgs regardless of the drain voltage Vds.

Next, additional descriptions are provided regarding the writing operation of the transistor 1. The writing operation of the transistor 1 can be performed by causing the drain current Ids with high current density to flow through the semiconductor thin film 13 for a fixed writing time when the gate voltage Vgs applied to the transistor 1 under the first characteristics is in a higher bias state than the range of drain voltage Vds. By causing the drain current Ids with high current density to flow through the semiconductor thin film 13 for a fixed writing time, joule heat and electromigration occurs in the semiconductor thin film 13 due to the drain current Ids, and the composition of the metal oxide semiconductor that forms the semiconductor thin film 13 changes, which is thought to be the cause for the characteristics change mentioned above being induced. In the present embodiment, the thickness of the semiconductor thin film 13 is constant, and the unit drain current (unit: A/μm) is in a proportional relationship with the current density (unit: A/m²) of the drain current. By increasing the unit drain current (unit: A/μm), the current density of the drain current (unit: A/m²) becomes large. In the present embodiment, it is assumed that the unit drain current is approximately 1 μA/μm to 1 mA/μm and the writing time is approximately 10 μs to 100 s. The unit drain current and the writing time for the writing operation change depending on the metal oxide semiconductor used in the semiconductor thin film 13 and the element structure of the transistor 1, and thus, the unit drain current and the writing time are not limited to the numerical range mentioned above.

In FIG. 10, an example of the relationship between the writing time (unit: ms) and the unit drain current (unit: A/μm) is shown. From FIG. 10, it can be seen that the greater the unit drain current is, the shorter the writing time is.

Furthermore, the writing characteristics also changes depending on the element structure of the transistor as mentioned above, and writing characteristics improve in an element structure in which joule heat is likely to occur or in an element structure in which the generated joule heat is difficult to diffuse.

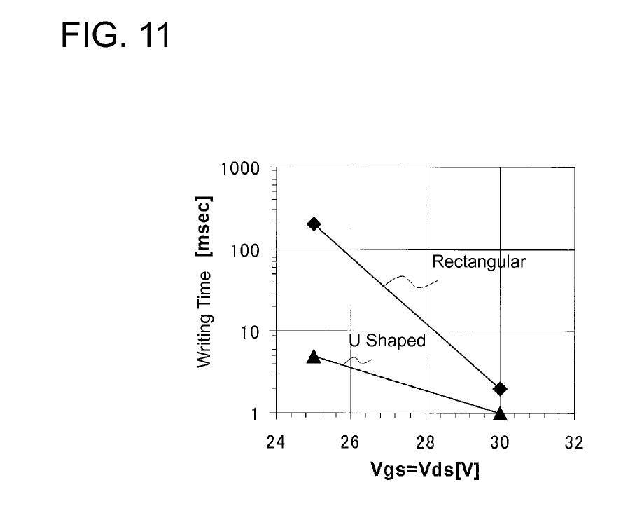

FIG. 11 shows an example of the relationship between the writing time (unit: ms) and the gate voltage Vgs and drain voltage Vds (Vgs=Vds) for two types of element structures including a structure in which the gap between the drain electrode and the source electrode is formed in a rectangular shape and one in which this gap is in a U shape. As shown in FIG. 11, if the gap is formed in a U shape, one of the drain electrode and the source electrode is surrounded by the other of the drain electrode and the source electrode, which causes the current density to be large in the surrounded electrode, resulting in a writing operation occurring. Thus, as long as the configuration has portions with high current density, the shape of the gap is not limited to a U shape. The results shown in FIG. 11 indicate that if two transistors 1 having different element structures are connected in series and respectively have the first characteristics, then even if the drain current of the same size is applied to both of the transistors 1, the current densities of the respective semiconductor thin films 13 differ. Thus, even if the writing operation in the transistor 1 with the higher current density is completed and the transistor 1 shifts to the second characteristics, because the writing operation of the transistor 1 with a lower current density is not completed and the first characteristics are kept therein, just one of the transistors 1 can be shifted to the second characteristics by blocking the drain current after the writing operation in one of the transistors 1 is completed.

If the high voltage gate voltage Vgs is applied to increase the drain current Ids for writing operation, there is a risk of breakdown of the gate insulating film 12. Thus, in the present embodiment, in order to increase the drain current Ids by keeping the gate voltage Vgs lower than the electric breakdown voltage of the gate insulating film 12, a material with high permittivity is used for the gate insulating film 12 to increase the electric capacitance. In the example above, the permittivity of the silicon nitride film (SiN) and the silicon nitride oxide film (SiNO) are higher than the permittivity of the silicon oxide film (SiO₂). However, the silicon oxide film (SiO₂) and the silicon oxide nitride film (SiON) include hydrogen in the film after being formed through the CVD method. Because the hydrogen reacts with the oxygen of the metal oxide semiconductor causing the semiconductor thin film 13 become closer to a conductor than a semiconductor, in order to make sure the semiconductor thin film 13 and the high permittivity film (silicon nitride film (SiN) or silicon nitride oxide film (SiNO)) do not come into direct contact, it is preferable that a silicon oxide film (SiO₂) or a silicon oxide nitride film (SiON) having low hydrogen concentration in the film be inserted therebetween.

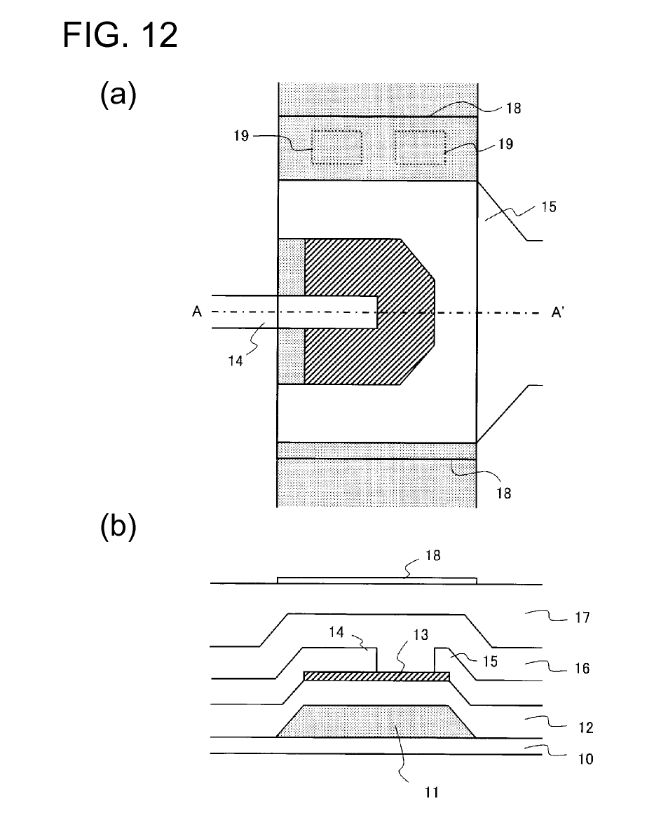

Furthermore, as shown in FIG. 12, as a method of increasing the drain current Ids during writing with the same gate voltage Vgs, it is preferable that at least a second gate electrode 18 cover the semiconductor thin film 13 through the second insulating film 16 and the third insulating film 17, that at least a portion of the second gate electrode 18 overlap the gate electrode 11, and that the second gate electrode 18 be connected to the gate electrode 11 through contact holes 19. As a result, the potential of the second gate electrode 18 and the gate electrode 11 becomes the same, and the drain current Ids becomes greater through the back gate effect, and the shift from the first characteristics to the second characteristics becomes more likely to occur. The plan view shown in FIG. 12(a) is a plan view shown through the second gate electrode 18.

Through the above-mentioned writing operation, the transistor 1 markedly shifts from the first characteristics to the second characteristics, and in particular, a large difference in the drain current Ids occurs when the gate voltage Vgs is within the specific voltage range (approximately 0.5V or less), and thus, by using the difference in current, the transistor 1 can be used as a non-volatile memory element. In other words, binary data of either 0 or 1 is assigned to the first characteristics before writing operation, and another of the binary data of 0 or 1 is assigned to the second characteristics after writing operation. Then, a prescribed voltage (0V, for example) within the specific voltage range is applied as the gate voltage Vgs, and by detecting the size of the drain current Ids, it is possible to tell whether the transistor 1 is in the first characteristic state or the second characteristic state.

Additionally, the transistor 1 can be used as a switching element under the first characteristics before the writing operation (initial state) because almost no drain current Ids flows and the transistor 1 is in an OFF state when the gate voltage Vgs is within the specific voltage range. Also, the transistor 1 under the first characteristics before the writing operation (initial state) can be used as an amplifying element because the drain current Ids respectively changes depending on the gate voltage Vgs and the drain voltage Vds if the gate voltage Vgs is higher than the specific voltage range. In addition, the transistor 1 can be used as a resistor, because the transistor 1 under the second characteristics after writing operation shows ohmic resistive characteristics.

During the manufacturing process of the transistor 1 shown in FIG. 2, in the manufacturing step of FIG. 2(c), the metal oxide semiconductor layer is removed by etching on a portion of the gate electrode 11, and the semiconductor thin film 13 is not formed there. In the manufacturing step of FIG. 2(d), the second conductive film is not removed by etching on portions of the gate electrode 11, thereby forming a capacitance element having the gate insulating film 12 sandwiched between the portion of the gate electrode 11 and the second conductive film that is kept.

Therefore, the transistor 1 can be used not only as a memory element, but also as a switching element, an amplifying element, and a resistor. Furthermore, as the capacitance element is formed with the same manufacturing process, various semiconductor devices using the transistor 1 can be configured. A semiconductor storage device having the transistor used as a memory circuit can be formed, a semiconductor device having a digital logic circuit using the transistor 1 as a switching element can be formed, a semiconductor device having an analog circuit using the transistor 1 as an amplifying element or a resistor can be formed, and a semiconductor device combining these elements can be formed, for example. The semiconductor device can be formed by combining other transistor elements that have a different element structure from the transistor 1.

Because the transistor 1 is formed as a thin film transistor, if the transistor 1 is used in a display device such as a liquid crystal display device that is formed on an insulating substrate, the various semiconductor devices mentioned above can be formed on the same insulating substrate as the display device.

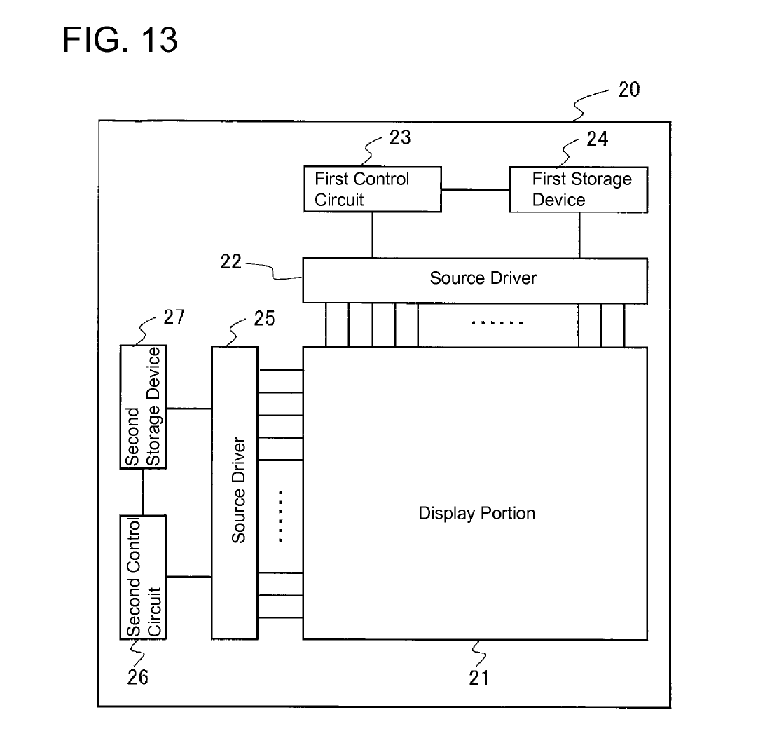

FIG. 13 shows a block diagram of a schematic configuration for when the transistor 1 is used in a display device 20. The display device 20 is formed of a display unit 21 having a plurality of pixels arranged in a matrix, a source driver 22 that drives a source line of each of the pixels, a first control circuit 23 that controls the timing of the source driver 22 and the source line voltage, a first storage device 24 that stores redundancy repair information of the source driver 22 and the configuration parameters necessary to drive the source lines, a gate driver 25 that drives a gate line of each of the pixels, a second control circuit 26 that controls the timing of the gate driver 25 and the gate line voltage, and a second storage device 27 that stores the redundancy repair information of the gate driver 25 and the configuration parameters that are necessary for driving the gate line. If the display device 20 receives display data and control signals from outside through a touch interface, then the first and the second control circuits 23 and 26 connect to a connecting terminal (not shown) that forms the touch interface, and if the display device 20 receives display data and control signals from outside through a non-touch interface, then the first and the second control circuits 23 and 26 connect to a wireless circuit (not shown) that forms the non-touch interface. If the transistor 1 is used as a memory element, then the transistor 1 is included in the first and second storage devices 24 and 27, and is used to store the configuration information of the display device 20, the ID, the redundancy repair information of each driver, and the configuration parameters needed to drive the source lines or the gate lines.

In addition, if the transistor 1 is used as a memory element, because the transistor 1 can be manufactured in relatively low temperatures, data can be stored in IDs of IC tags and the like. The transistor 1 can also be used as a storage device with large capacitance for digital signage because the transistor 1 can be manufactured using a transparent material. Furthermore, by using the transistor 1 as a program element of a logic circuit instead of a storage device, a programmable logic circuit device such as ASIC (Application Specific Integrated Circuit) and FPGA (Field-Programmable Gate Array) can be realized.

### Embodiment 2

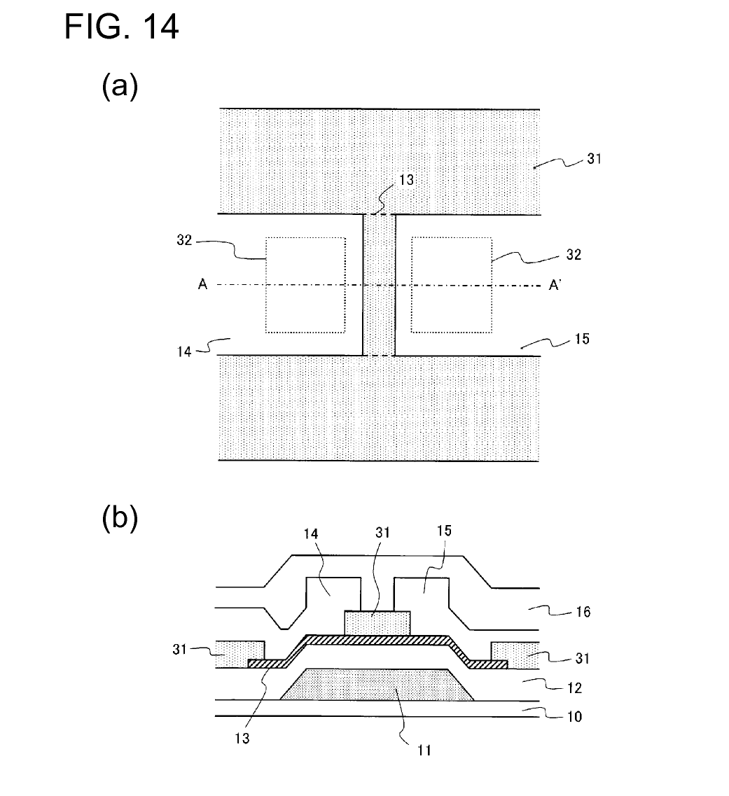

FIG. 14 shows an example of an element structure of a present transistor 2 of Embodiment 2. FIG. 14(a) schematically shows a plan view structure of the transistor 2 and FIG. 14(b) schematically shows a cross-sectional structure of the transistor 2. In the respective figures, main components of the transistor 2 are emphasized, and therefore, the dimensions of the respective components are not always the same as the dimensions of the actual device. FIG. 14(b) is a cross-sectional view of FIG. 14(a) along the line A-A′. In the plan view of FIG. 14(a), a case in which the gap between the source electrode 14 and the drain electrode 15 on the semiconductor thin film 13 is rectangular in a plan view is shown, but the gap can have a U shape shown in the plan view of FIG. 1(a) of Embodiment 1. In the plan view of FIG. 14(a), openings 32 in an etching stopper layer 31 disposed below the source electrode 14 and the drain electrode 15 are shown with dotted lines, and the side walls of the semiconductor thin film 13 positioned below the etching stopper layer 31 are shown as dotted lines.

As can be seen from comparing FIG. 1 and FIG. 14, the transistor 2 of Embodiment 2 has essentially the same element structure as the transistor 1 of Embodiment 1. A particular difference (first difference) is that the transistor 2 of Embodiment 2 has the etching stopper layer 31 on a portion of the semiconductor thin film 13, and the semiconductor thin film 13 is in contact with the source electrode 14 and the drain electrode 15 through the opening 32 of the etching stopper layer 31. The second difference is that the semiconductor thin film 13 is formed so as to extend beyond the gate electrode 11 in the gate length L direction. The etching stopper layer 31 is the second insulating film after the gate insulating film 12, but for terminological consistency with Embodiment 1, the term “second insulating film” is not used, and the insulating film that is the same as the second insulating film 16 (the third insulating film in Embodiment 2) in Embodiment 1 is also referred to as the second insulating film 16 in Embodiment 2.

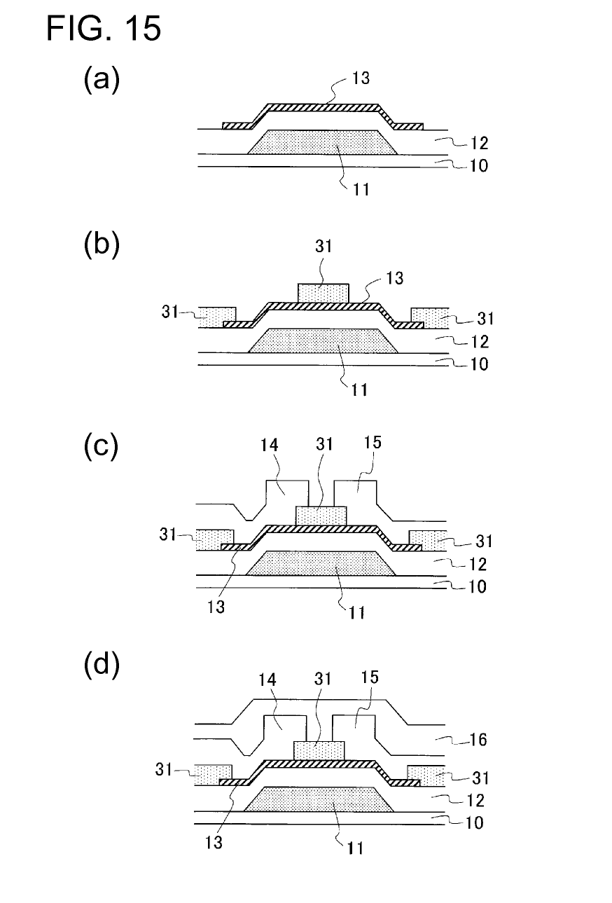

Next, the manufacturing method of the transistor 2 and details of the respective components are described with reference to the cross-sectional views of FIG. 15. The cross-sections of an element in FIG. 15 at the respective steps are cross-sections of FIG. 14(a) along the line A-A′. Descriptions already made in Embodiment 1 are omitted here.

As shown in FIG. 15(a), the first conductive film is formed on the entire surface of the insulating substrate 10, and the gate electrode 11 is formed by patterning the first conductive film using a known dry etching method, and then, the gate insulating film 12 is formed on the entirety of the exposed surfaces of the insulating substrate 10 and the gate electrode 11, a metal oxide semiconductor film is formed on the entire gate insulating film 12, and the semiconductor thin film 13 is formed by patterning the metal oxide semiconductor film using a known wet etching method. The forming method, the material, the structure, the thickness, and the like of the first conductive film, the gate insulating film 12, and the semiconductor thin film 13 are the same as Embodiment 1.

Next, as shown in FIG. 15(b), the etching stopper layer 31 is formed on the entirety of the exposed surfaces of the gate insulating film 12 and the semiconductor thin film 13 by plasma CVD or sputtering, and then patterned using a known dry etching method. Next, annealing is performed for 30 minutes to 4 hours at a temperature of 200° C. to 450° C. in air. The etching stopper layer 31 is formed of a multilayer film having a single layer film or a multilayer film of two or more layers selected from among a silicon oxide film (SiO₂), a silicon nitride film (SiN), a silicon nitride oxide film (SiNO), a silicon oxide nitride (SiON) film, an aluminum oxide (Al₂O₃), and a tantalum oxide (Ta₂O₅). In the present embodiment, a double layer film of SiO₂ having a thickness of 10 nm to 500 nm is used as an example.

The etching stopper layer 31 covers the exposed surface of the gate insulating film 12, and the etching stopper layer 31 is formed as the base layer on the semiconductor thin film 13 for portions of the second conductive film that are removed by etching to form the source electrode 14 and the drain electrode 15 in a later step.

Next, as shown in FIG. 15(c), the second conductive film is formed on the entirety of the surfaces of the exposed semiconductor thin film 13 and the etching stopper layer 31, and the source electrode 14 and the drain electrode 15 are respectively formed by a known dry etching method. The source electrode 14 and the drain electrode 15 are separated from each other and are respectively in contact with a portion of the semiconductor thin film 13 through the openings in the etching stopper layer 31. In the present embodiment, as shown in FIG. 14(a), the gap, which is located between an area of the source electrode 14 and the drain electrode 15 that are respectively in contact with the semiconductor thin film 13, has a rectangular shape as an example. The forming method, the material, the structure, the thickness, and the like of the second conductive film are the same as in Embodiment 1.

Next, as shown in FIG. 15(d), the second insulating film 16 is formed on the entirety of the surfaces of the exposed etching stopper layer 31, the semiconductor thin film 13, the source electrode 14, and the drain electrode 15. Next, annealing is performed for 30 minutes to 4 hours at a temperature of 200° C. to 400° C. in air. The forming method, the material, the structure, the thickness, and the like of the second insulating film 16 are the same as in Embodiment 1.

The transistor 2 is manufactured by the respective steps mentioned above. A third insulating film (not shown) such as a photosensitive resin is formed as a planarizing film that planarizes the surface of the second insulating film 16 in a similar manner to Embodiment 1, and then this photosensitive resin film is exposed, developed, and baked. Additionally, etching is performed on the third insulating film and the second insulating film 16 that are formed, and contact holes (not shown) are formed to connect the gate electrode 11, the source electrode 14, the drain electrode 15, and the like to the metal wiring line layer (ITO or the like, for example) formed on the third insulating film. The third insulating film may be formed alone without forming the second insulating film 16.

Because the transistor 2 of Embodiment 2 has the etching stopper layer 31, damage to the semiconductor thin film 13 during the etching of the second conductive film can be avoided, and the fluctuation in electric characteristics due to the variation in electric characteristics and electric stress in the transistor 2 is decreased compared to the transistor of Embodiment 1. Furthermore, because the first and second conductive films can directly contact each other, the size of the circuit area can be reduced due to the size of the contact hole being reduced.

In Embodiment 2, during the manufacturing process of the transistor 2 shown in FIG. 15, in the manufacturing step of FIG. 15(b), the etching stopper layer 31 is removed by etching on a portion of the gate electrode 11, and the etching stopper layer 31 is not formed there, and in the manufacturing step of FIG. 15(c), a capacitance element sandwiching the gate insulating film 12 and the etching stopper layer 31 is formed between the portion of the gate electrode 11 and the second conductive film that is kept by keeping the second conductive film over a portion of the gate electrode 11.

The electric characteristics, the writing operation, and the applications of the transistor 2 of Embodiment 2 are essentially the same as those explained in Embodiment 1 and redundant descriptions thereof are omitted.

### Embodiment 3

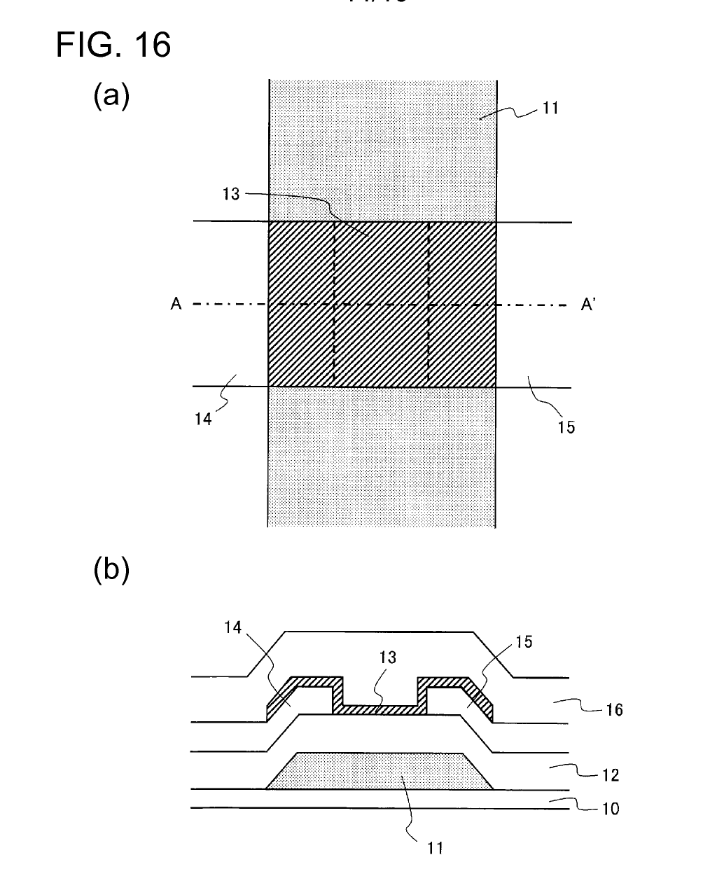

FIG. 16 shows an example of an element structure of a present transistor 3 of Embodiment 3. FIG. 16(a) schematically shows a plan view structure of the transistor 3 and FIG. 16(b) schematically shows a cross-sectional structure of the transistor 3. In the respective figures, main components of the transistor 1 are emphasized, and therefore, the dimensions of the respective components are not always the same as the dimensions of the actual device. FIG. 16(b) is a cross-sectional view of FIG. 16(a) along the line A-A′. In the plan view of FIG. 16(a), a case in which the gap between a source electrode 14 and a drain electrode 15 on the semiconductor thin film 13 is rectangular in a plan view is shown, but the shape can be a U shape as shown in the plan view of FIG. 1(a) of Embodiment 1.

As can be seen from comparing FIG. 1 and FIG. 16, the transistor 3 of Embodiment 3 essentially has the same element structure as the transistor 1 of Embodiment 1. A difference in particular is that in the transistor 3 of Embodiment 3, the source electrode 14 and the drain electrode 15 are in contact with the bottom surface of the semiconductor thin film 13. Therefore, unlike Embodiment 1, the source electrode 14 and the drain electrode 15 are formed before the semiconductor thin film 13.

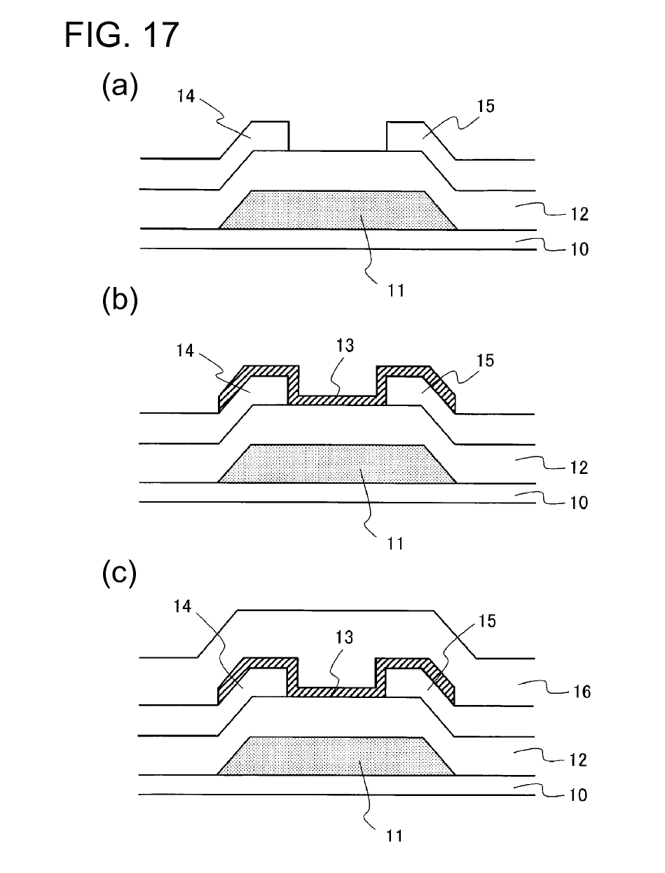

Next, the manufacturing method of the transistor 2 and details of the respective constituting elements are described with reference to the cross-sectional views of FIG. 17. The cross-sections of an element in FIG. 17 showing cross-sections of respective steps are cross-sections of FIG. 16(a) along the line A-A′. Descriptions already made in Embodiment 1 are omitted here.

As shown in FIG. 17(a), the first conductive film is formed on the entire surface of an insulating substrate 10, and a gate electrode 11 is formed by patterning the first conductive film using a known dry etching method. Then, a gate insulating film 12 is formed on the entirety of the surfaces of the exposed insulating substrate 10 and the gate electrode 11, a second conductive film is formed on the entire surface of the gate insulating film 12, and the source electrode 14 and the drain electrode 15 that are separated from each other are respectively formed by patterning the second conductive film using a known method of dry etching. In the present embodiment, as shown in FIG. 16(a), the gap between the source electrode 14 and the drain electrode 15 is in a rectangular shape in a plan view. The forming method, the material, the structure, the thickness, and the like of the first conductive film, the gate insulating film 12, and the semiconductor thin film 13 are the same as in Embodiment 1.

Next, as shown in FIG. 17(b), a metal oxide semiconductor layer is formed on the entire surface of the exposed gate insulating film 13, the source electrode 14, and the drain electrode 15, and a semiconductor thin film 13 is formed by patterning the metal oxide semiconductor layer using a known wet etching method. The semiconductor thin film 13 is respectively connected to the source electrode 14 and the drain electrode 15. The forming method, the material, the structure, the thickness, and the like of the metal oxide semiconductor layer are the same as in Embodiment 1.

Next, as shown in FIG. 17(c), a second insulating film 16 is formed on an entire surface of the exposed second conductive film (source electrode 14 and drain electrode 15) and the semiconductor thin film 13. Next, annealing is performed for 30 minutes to 4 hours at a temperature of 200° C. to 400° C. in air. The forming method, the material, the structure, the thickness, and the like of the second insulating film 16 are the same as in Embodiment 1.

The transistor 3 is manufactured by the respective steps mentioned above. A third insulating film (not shown) such as a photosensitive resin is formed as a planarizing film that planarizes the surface of the second insulating film 16 in a similar manner to Embodiment 1, and then this photosensitive resin film is exposed, developed, and baked. Additionally, etching is performed on the third insulating film and the second insulating film 16 that are formed, and contact holes (not shown) are formed to connect the gate electrode 11, the source electrode 14, the drain electrode 15, and the like to the metal wiring line layer (ITO or the like, for example) formed on the third insulating film. The third insulating film may be formed alone without forming the second insulating film 16.

In the transistor 3 of Embodiment 3, the source electrode 14 and the drain electrode 15 are formed before the semiconductor thin film 13, and thus, no etching damage occurs on the semiconductor thin film 13 while etching is performed on the second conductive film. Therefore, fluctuation of electric characteristics is decreased compared to the transistor of Embodiment 1 due to the variation in electric characteristics and electric stress in the transistor 3. Furthermore, compared to Embodiment 2, Embodiment 3 is advantageous in terms of manufacturing cost and yield because the etching stopper layer 31 does not need to be formed, which simplifies the manufacturing process.

Also in Embodiment 3, during the manufacturing process of the transistor 3 shown in FIG. 17, in the manufacturing step of FIG. 17(a), the second conductive film is kept over a portion of the gate electrode 11, thereby forming a capacitance element in which the portion of the gate electrode 11 and the remaining portion of the second conductive film sandwich the gate insulating film 12.

The electric characteristics, the writing operation, and the applications of the transistor 3 of Embodiment 3 are essentially the same as those explained in Embodiment 1 and redundant descriptions are omitted.

### Other Embodiments

(1) In the respective embodiments above, examples of the transistors 1 to 3 formed of bottom gate type thin film transistors were shown, but the transistors 1 to 3 are not limited to bottom gate type thin film transistors.

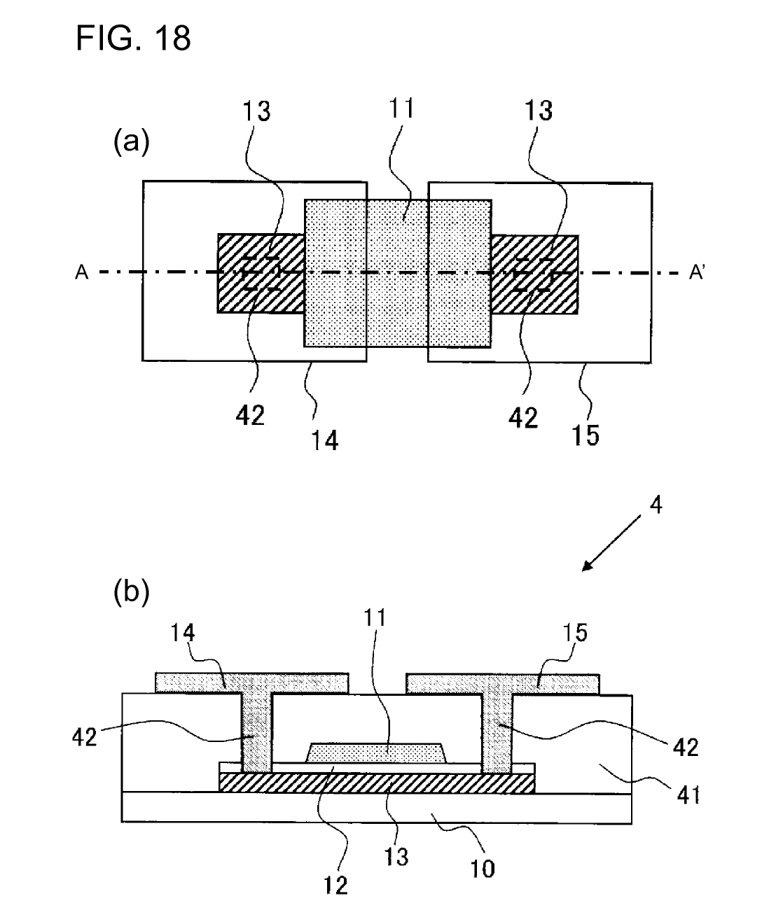

In FIG. 18, an example of an element structure of a present transistor 4 formed of a top gate type thin film transistor is shown. FIG. 18(a) schematically shows a plan view structure of the transistor 4 and FIG. 18(b) schematically shows a cross-sectional structure of the transistor 4. In the respective figures, main components of the transistor 4 are emphasized, and therefore, the dimensions of the respective components are not always the same as the dimensions of the actual device. FIG. 18(b) is a cross-sectional view of FIG. 18(a) along the line A-A′.

The transistor 4 has a semiconductor thin film 13 formed of a metal oxide semiconductor, a gate insulating film 12, and a gate electrode 11 formed in that order on an insulating substrate 10 such as a glass substrate, and an interlayer insulating film 41 formed on top of these. A source electrode 14 and a drain electrode 15 formed on the interlayer insulating film 41 are in contact with the semiconductor thin film 13 through the contact holes 42.

The transistors 1 to 4 of the respective embodiments and other embodiment show cases in which the transistors 1 to 4 are thin film transistors, but even if the transistor has a MOS type structure by forming the semiconductor thin film 13 of a metal oxide semiconductor on a silicon substrate instead of the insulating substrate 10, a metal oxide transistor that shifts from the first characteristics to the second characteristics can be realized.

(2) In the respective embodiments, an n-channel present transistor using IGZO as the n-channel type metal oxide semiconductor of the semiconductor thin film 13 is described as an example, but the conductivity type of the transistor is not limited to the n-channel type.

(3) The respective conductive films, the respective materials of the insulating films, the structure, the thicknesses, the electric characteristics, and writing characteristics of the transistors described in the respective embodiments are just examples and the present invention is not limited to the descriptions provided in the respective embodiments. Industrial Applicability

The present invention can be used for metal oxide transistors having channel regions formed of metal oxide semiconductors, and for semiconductor devices and electronic devices using such transistors.

### DESCRIPTION OF REFERENCE CHARACTERS

1-4 metal oxide transistor
10 insulating substrate
11 gate electrode
12 first insulating film (gate insulating film)
13 semiconductor thin film (metal oxide semiconductor)
14 source electrode
15 drain electrode
16 second insulating film
17 third insulating film
18 second gate electrode
19 contact hole
20 display device
21 display unit
22 source driver
23 first control circuit
24 first storage device
25 gate driver
26 second control circuit
27 second storage device
31 etching stopper layer
32 opening of etching stopper layer
41 interlayer insulating film
42 contact hole

1. A metal oxide transistor comprising:
a semiconductor thin film formed of a metal oxide semiconductor;
a source electrode in contact with a portion of the semiconductor thin film;
a drain electrode in contact with another portion of the semiconductor thin film; and
a gate electrode facing the semiconductor thin film through a gate insulating film,
wherein the metal oxide transistor is configured to exhibit, as an initial state, first characteristics, which are transistor characteristics, in which a drain current flowing from the drain electrode to the source electrode changes depending on a gate voltage applied between the gate electrode and the source electrode and a drain voltage applied between the drain electrode and the source electrode,
wherein the metal oxide transistor is configured to make a transition from the first characteristics to second characteristics when the drain current having a prescribed current density or greater that induces a change from the first characteristics is caused to flow through the semiconductor thin film for a prescribed period of time, the second characteristics being such that the dependence of the drain current on the gate voltage is smaller in the second characteristics than in the first characteristics, whereby changes in the drain current primarily depends on the drain voltage and not on the gate voltage, exhibiting ohmic resistive characteristics,
wherein, in the first characteristics, there exists a specific voltage range of the gate voltage at which the metal oxide transistor enters a minute current state, the minute current state being such that an absolute value of a unit drain current that is the drain current for each unit channel width is confined to be less than or equal to 1×10⁻¹⁴ A/μm at least when an absolute value of the drain voltage is in a range of 0.1V to 10V, and
wherein, in the second characteristics, the absolute value of the unit drain current is greater than or equal to 1×10⁻¹¹ A/μm regardless of the gate voltage, when the drain voltage is at least within a range of 0.1V to 10V, even if the gate voltage is within said specific voltage range.

2. The metal oxide transistor according to claim 1, wherein said metal oxide transistor is a thin film transistor in which the semiconductor thin film, the source electrode, the drain electrode, the gate electrode, and the gate insulating film are formed on an insulating substrate.

3. The metal oxide transistor according to claim 1, wherein the metal oxide semiconductor includes In, Ga, or Zn.

4. The metal oxide transistor according to claim 3, wherein the metal oxide semiconductor includes InGaZnOx.

5. The metal oxide transistor according to claim 1, wherein the current density of the drain current is greater in a portion of the semiconductor thin film than in another portion.

6. The metal oxide transistor according to claim 1, wherein an area sandwiched by the drain electrode and the source electrode has a U shape.

7. The metal oxide transistor according to claim 1,
wherein the gate insulating film has a multilayer structure having at least a first insulating film and a second insulating film having higher permittivity than the first insulating film,
wherein the first insulating film has a lower hydrogen concentration therein than the second insulating film after being formed, and
wherein the first insulating film is formed between the semiconductor thin film and the second insulating film.

8. The metal oxide transistor according to claim 1, further comprising: a second gate electrode facing the semiconductor thin film through an insulating film other than the gate insulating film, the second gate electrode being provided across from the gate electrode with the semiconductor thin film therebetween.

9. The metal oxide transistor according to claim 1, wherein the change from the first characteristics to the second characteristics occurs due to a change in composition ratio of elements forming the metal oxide semiconductor of the semiconductor thin film through joule heat generated by the drain current.

10. A semiconductor device comprising: the metal oxide transistor according to claim 1.

11. A method of driving the metal oxide transistor according to claim 1, comprising: causing the drain current having the prescribed current density or greater to flow between the drain electrode and the source electrode for the prescribed period of time when the metal oxide transistor is exhibiting the first characteristics, so as to cause the metal oxide transistor to make the transition from the first characteristics to the second characteristics.
